(19) United States
(12) Patent Application Publication
(10) Pub. No.: US 2003/0101407 A1
(43) Pub. Date: May 29, 2003

(54) Selectable complexity turbo coding system

(75) Inventors: Meir Ariel, Tel Aviv (IL); Ofer Amrani, Tel Aviv (IL)

Correspondence Address: G.E. EHRLICH (1995) LTD., c/o ANTHONY CASTORINA, SUITE 207, 2001 JEFFERSON DAVIS HIGHWAY, ARLINGTON, VA, 22202, US

(73) Assignee: CUTE Ltd.

(21) Appl. No.: 09/986,502

(22) Filed: Nov. 9, 2001

(51) Int. Cl. H04L 5/12; H04L 23/02; H03M 13/00

(52) U.S. Cl. 714/774

(57) ABSTRACT

A switchable-output encoder for encoding an input data sequence into an error protection encoded output sequence is switchable between two encoding modes. The encoder modes comprise a relatively complex mode suitable for a relatively high noise level channel and a relatively simple mode suitable for a relatively low noise level channel. A corresponding decoder is also discussed.

### FIELD OF THE INVENTION

The present invention relates to switchable encoding and decoding of a data sequence, and more particularly but not exclusively to switchable turbo code encoding and decoding.

### BACKGROUND OF THE INVENTION

Turbo codes are employed in modern digital communication systems to protect high bit-rate transmitted information from error. Turbo codes are generally constructed as a concatenation of two recursive systematic convolutional codes, linked together by some non-uniform interleaving. The term turbo code originally described the parallel concatenation of two recursive systematic convolutional codes (PCCC). Other possibilities are serial concatenation (SCCC) and using block codes as component codes. PCCC is now becoming a standard error correction scheme in several wireless air interfaces. For example, the 3GPP (Third Generation Partnership Project for wireless systems) standard employs a PCCC with M=8 states and a block length of up to N=5120 information bits. In a cdma2000 system, N can be as high as 20000.

Although convolutional in nature, turbo codes cannot be decoded directly using a Viterbi decoder. The Viterbi decoding algorithm models a code as a trellis, with branches depicting legal transitions from state to state. Each state represents a combination of input digits used by the encoder to select the transmitted symbol, and each branch is associated with a branch metric. As each symbol in the received sequence is processed, the Euclidean distance between the received symbol and each possible path through the trellis is measured. A single surviving path is selected for each state.

A trellis diagram corresponding to a turbo code typically has a huge number of states, making implementation of the Viterbi algorithm impractical. Therefore, an iterative approach is employed with two elementary decoders, each associated with one of the two constituent codes. The two decoders are usually serially concatenated, where the first decoder yields weighted, or soft-output decisions that are fed to the second decoder as a priori information. The soft-outputs of the second decoder are then fed back to the first decoder for the second iteration, and so on. Only the so-called extrinsic information, i.e. new information that is generated by the decoder, is passed between the decoders.

The optimal soft-output decoder is the so-called MAP (maximum a posteriori) decoder, which uses both backward and forward decoding to efficiently determine the soft output. The MAP decoder is optimal in the sense that it minimizes the decoded bit error probability for each information bit based on all received bits. However, because of memory, processing, and numerical tradeoffs, MAP decoding is usually limited to a sub-optimal approximation. Typically, convolutional codes composing a turbo code are graphically represented as a trellis. MAP-type decoders (log-MAP, MAP, max-log-MAP, constant-log-MAP, etc.) utilize forward and backward generalized Viterbi recursions on the trellis in order to provide soft outputs, as is known in the art.

Because of the Markov nature of the encoded sequence (wherein previous states cannot affect future states or future output branches), the MAP bit probability can be broken into the past (beginning of trellis to the present state), the present state (branch metric for the current value), and the future (end of trellis to current value). More specifically, the MAP decoder performs forward and backward recursions up to a present state, wherein the past and future probabilities are used along with the present branch metric to generate an output decision. The principles of providing soft output decisions are well known in the art, and several variations of the above-described decoding methods exist.

Most of the soft-input soft-output (SISO) decoders considered for turbo codes are based on the MAP algorithm in a paper by L. R. Bahl, J. Cocke, F. Jelinek, and J. Raviv entitled “Optimal Decoding of Linear Codes for Minimizing Symbol Error Rate”, IEEE Transactions on Information Theory, Vol. IT-20, March 1974, pp. 284-7 (the “BCJR algorithm” or “BCJR method”). MAP algorithms not only minimize the probability of error for an information bit given the received sequence, they also provide the probability that the information bit is either a 1 or 0 given the received sequence. The BCJRdecoding algorithm provides a soft output decision for each bit position (trellis section) wherein the influences of the soft inputs within the block are broken into contributions from the past (earlier soft inputs), the present soft input, and the future (later soft inputs). The BCJR decoder algorithm requires a forward and a backward generalized Viterbi recursion on the trellis to arrive at an optimal soft output for each trellis section, or stage. These a posteriori probabilities, or more commonly the log-likelihood ratio (LLR) of the probabilities, are passed between SISO decoding steps in iterative turbo decoding. The LLR for information bit uₜ is:

$${Λ}_{t} = log \frac{{\sum }_{( m , n ) ∈ {B}^{1}}^{} {α}_{t - 1} ( n ) {γ}_{t} ( n , m ) {β}_{t} ( m )}{{\sum }_{( m , n ) ∈ {B}^{0}} {α}_{t - 1} ( n ) {γ}_{t} ( n , m ) {β}_{t} ( m )} ,$$

for all bits in the decoded sequence (t=1 to N). In equation (1), the probability that the decoded bit is equal to 1 (or 0) in the trellis given the received sequence is composed of a product of terms due to the Markov property of the code. The Markov property may be stated as the assumption that the past and the future are independent given the present. The present, γₜ(n,m), may be regarded as the probability of being in state m at time t and generating the symbol γₜ when the previous state at time t−1 was n. The present operates as a branch metric. The past, αₜ(m), may be regarded as the probability of being in state m at time t with the received sequence {y₁, . . . , yₜ}, and the future, βₜ(m), may be regarded as probability of generating the received sequence {yₜ₊₁, . . . , y_{N}} from state m at time t. The probability αₜ(m) can be expressed as function of αₜ₋₁(m) and γₜ(n,m) and is called the forward recursion.

$${α}_{t} ( m ) = {\sum }_{n = 0}^{M - 1} {α}_{t - 1} ( n ) {γ}_{t} ( n , m ) , m = 0 , … , M - 1 ,$$

where M is the number of states. The reverse or backward recursion for computing the probability βₜ(n) from βₜ₊₁(n) and γₜ(n,m) is:

$${β}_{t} ( n ) = {\sum }_{m = 0}^{M - 1} {β}_{t + 1} ( m ) {γ}_{t} ( n , m ) , n = 0 , … , M - 1.$$

The overall aposteriori probabilities in equation (1) are computed by summing over the branches in the trellis B¹(B⁰) that correspond to uₜ=1(or 0).

The LLR in equation (1) requires both the forward and backward recursions to be available at time t. The BCJR method for meeting this requirement is to compute and store the entire backward recursion, and recursively compute αₜ(m) and Λₜ from t=1 to t=N using αₜ₋₁ and βₜ.

In terms of computational complexity, the BCJR method requires N*M state updates for the backward recursion (M state updates per trellis section, N trellis sections in the code) and provides optimal performance. In practice, a backward recursion is first performed by a processor across the entire block and stored in memory. The processor then performs a forward recursion. The results of the backward and forward recursions are used with the present state and stored future state to arrive at a soft output decision for each stage. In this case the processor operates on each state twice, once to generate and store the backward recursion states, and once to generate the forward recursion state.

To address the computational complexity and memory utilization problems of the soft output decoder, a sliding window method was developed. The sliding window technique is described in a paper by S. Benedetto, D. Divsalar, G. Montorsi, and F. Pollara, entitled “Algorithm for continuous decoding of turbo codes,” Electronics Letters, Vol. 32, Feb. 15, 1996, pp. 314-315.

Another prior art decoder, described in U.S. Pat. No. 5,933,462 to Viterbi et al. (and similarly in a paper of S. Pietrobon and S. Barbulescu, “A Simplification of the Modified Bahl et al. Decoding Algorithm for Systematic Convolutional Codes,” Int. Symp. On Inform. Theory and its Applications, Sydney, Australia, pp. 1073-7, November 1994, revised Jan. 4, 1996 and S. Pietrobon, “Efficient Implementation of Continuous MAP Decoders and a Synchronisation Technique for Turbo Decoders,” Int. Symp. On Inform. Theory and its Applications, Victoria, B. C., Canada, pp. 586-9, September 1996) comprises another sliding window technique.

The use of even the sub-optimal Max-Log-MAP algorithm for constituent code decoding makes heavy demands on processing resources. One prior art implementation of this algorithm, the Max-Log-MAP algorithm on the Motorola DSP56603 80 MIPS DSP, enables performance of 48.6 kbit/s. Given such a performance level, forty processors must work in parallel in order to provide the target real-time performance of 2 Mbit/s, as defined in the 3G standards.

Another prior art device is the state-of-the-art Motorola StarCore SC140 DSP, which cannot support a processing rate of more than 1 Mbit/s. A hand written assembly code required 36 cycles per code/iteration/bit, resulting in 288 cycles per 4 iterations, or equivalently ˜1 Mbit/s on a 300M cycles per second DSP.

### SUMMARY OF THE INVENTION

It is a purpose of the present embodiments to provide a switchable data coding system that can be deployed in cellular wireless networks, to trade data rate with SINR when the conditions allow an increase in the SINR.

It is a purpose of the present embodiments to provide a data coding system that can be easily implemented in exsiting turbo encoders and decoders.

According to a first aspect of the present invention there is thus provided a switchable-output encoder for encoding an input data sequence to form an error protection encoded output sequence. The encoder is switchable between two encoding modes. The modes comprise a relatively complex mode suitable for a relatively high noise level channel and a relatively simple mode suitable for a relatively low noise level channel, wherein the relatively complex mode comprises a turbo coding mode.

In a preferred embodiment, the relatively simple mode comprises a degenerated version of the relatively complex mode.

In a further preferred embodiment, the relatively simple mode comprises a degenerated turbo coding mode.

In another preferred embodiment, the relatively simple mode comprises a convolutional coding mode.

In a further preferred embodiment, in the turbo coding mode, the output sequence comprises a multiplexed sequence containing at least three sub-sequences. The sub-sequences including a data sequence, a first coded sequence formable by encoding the data sequence, and a second coded sequence formable by interleaving the data sequence into an interleaved sequence and encoding the interleaved sequence.

In a further preferred embodiment, in the degenerated turbo coding mode, the output sequence comprises a multiplexed sequence containing at least three sub-sequences. The sub-sequences include a data sequence, a first coded sequence formable by encoding the data sequence, and an interleaved sequence formable by interleaving the data sequence.

In another preferred embodiment, the switchable-output encoder comprises a first sub-encoder, to encode the input data sequence into a first coded sequence.

In a further preferred embodiment, the encoder comprises an interleaver, to interleave the input data sequence into an interleaved sequence.

In another preferred embodiment, the encoder further comprises a second sub-encoder, connected to the interleaver, to encode the interleaved data sequence into a second coded sequence.

In a preferred embodiment, the encoder further comprises a switch connected to the interleaver and to the second sub-encoder, wherein the switch is operable to provide one of the interleaved sequence and the second coded sequence as a switch output sequence, thereby affecting the composition of the encoder output sequence.

In a further preferred embodiment, the encoder further comprises an automatic controller, connected to the switch, the automatic controller being operable to monitor predetermined communication parameters in order to determine a required one of the encoder modes, and to control switch operation accordingly.

In a preferred embodiment, in order to provide the turbo coding mode, the switch is settable to send the second coded sequence for output. In order to provide the degenerated turbo coding mode, the switch is settable to send the interleaved sequence for output.

In a further preferred embodiment, the encoder further comprises a multiplexer, connected to the encoder input, to the first sub-encoder, and to the switch, to multiplex the input data sequence, the first encoded sequence, and the switch output sequence into a single multiplexed sequence.

In another preferred embodiment, the multiplexed sequence serves as the error-protection encoded output sequence.

In a preferred embodiment, the first sub-encoder comprises a convolutional coder.

In a further preferred embodiment, the second sub-encoder comprises a convolutional coder.

In another preferred embodiment, the first sub-encoder and the second sub-encoder are recursive systematic convolutional encoders.

According to a second aspect of the present invention there is thus provided a switchable decoder for decoding a received sequence comprising error-protection encoded data, received from a noisy channel into an estimate of an input sequence, wherein the decoder is switchable between two modes, the modes comprising a relatively complex decoding mode suitable for a relatively high noise level channel and a relatively simple decoding mode suitable for a relatively low noise level channel, and wherein the relatively complex mode comprises a turbo decoding mode.

In a preferred embodiment, the relatively simple decoding mode comprises a degenerated version of the relatively complex decoding mode.

In a further preferred embodiment, the relatively simple decoding mode comprises a degenerated turbo decoding mode.

In another preferred embodiment, the relatively simple decoding mode comprises a convolutional decoding mode.

In a preferred embodiment the decoder is operable to process the received sequence as a multiplexed sequence comprising at least three component sub-sequences.

In a preferred embodiment, when the decoder is in degenerated turbo decoding mode, the decoder is operable to process the first sub-sequence as a data sequence, the second sub-sequence as a directly encoded sub-sequence, and the third sub-sequence as an interleaved data sub-sequence.

In a preferred embodiment, the decoder comprises a separator, operable to separate the received data sequence into a first, a second, and a third data sub-sequence.

In a preferred embodiment, the decoder further comprises a first switch, connected to the sub-decoders, wherein the first switch is operable to connect the decoder output to the first sub-decoder output when the decoder is in relatively complex decoding mode, and to connect the decoder output to the second sub-decoder output when the decoder is in relatively simple decoding mode.

In a further preferred embodiment, the first sub-decoder is operable as a turbo decoder, and the second sub-decoder is operable as a degenerated turbo decoder.

In another preferred embodiment, the degenerated turbo decoder comprises a de-interleaver for de-interleaving the third sub-sequence to form a de-interleaved sub-sequence.

In a further preferred embodiment, the degenerated turbo decoder further comprises a convolutional code decoder for decoding the first sub-sequence, the second sub-sequence, and the de-interleaved sub-sequence into the estimate of an input sequence.

In a preferred embodiment, the convolutional code decoder comprises a hard-decision trellis decoder.

In another preferred embodiment, the convolutional code decoder comprises a soft-decision trellis decoder.

In a preferred embodiment, the decoder further comprises a second switch, connected to the separator, wherein when the decoder is in relatively complex decoding mode the second switch is settable to connect the separator output sub-sequences to inputs of the first sub-decoder, and when the decoder is in relatively simple decoding mode the second switch is settable to connect the separator outputs to inputs of the second sub-decoder.

In a preferred embodiment, the decoder further comprises an automatic controller connected to the first switch, the automatic controller being operable to monitor predetermined communication parameters in order to determine a required one of the decoder modes, and to control switch operation accordingly.

In a preferred embodiment, the decoder further comprises an automatic controller, connected to the second switch, the automatic controller being operable to monitor predetermined communication parameters in order to determine a required one of the decoder modes, and to control switch operation accordingly.

According to a third aspect of the present invention there is thus provided a switchable data encoder-decoder system, comprising a switchable-output encoder for encoding an input sequence to form an error protection encoded output sequence and a switchable decoder, for decoding a received sequence into an estimate of the input sequence, wherein the encoder and the decoder are synchronously switchable between two modes of operation, the modes comprising a relatively complex mode suitable for a relatively high noise level channel and a relatively simple mode suitable for a relatively low noise level channel, and wherein the relatively complex mode comprises a turbo coding/decoding mode.

In a preferred embodiment, the relatively simple mode comprises a degenerated version of the relatively complex mode.

In a further preferred embodiment, the relatively simple mode comprises a degenerated turbo coding/decoding mode.

In a further preferred embodiment, the relatively simple mode comprises a convolutional coding/decoding mode.

In another preferred embodiment, when the encoder-decoder system is in turbo coding/decoding mode the encoder is operable to output a multiplexed signal comprising three sub-sequences, the sub-sequences comprising the input data sequence, a first coded sequence, and an interleaved and encoded data sequence.

In a further preferred embodiment, when the encoder-decoder system is in degenerated turbo coding/decoding mode the encoder is operable to output a multiplexed signal comprising three sub-sequences, the sub-sequences comprising the input data sequence, a first coded sequence, and an interleaved data sequence.

In a further preferred embodiment, when the encoder-decoder system is in degenerated turbo coding/decoding mode the decoder is operable to decode a received version of a multiplexed signal comprising the input data sequence, a first coded sequence, and an interleaved data sequence into an estimate of the input sequence.

In a preferred embodiment, the encoder comprises: an interleaver, a first sub-encoder, a second sub-encoder connected to the interleaver, a switch connected to the interleaver and to the second sub-encoder, and a multiplexer connected to the encoder input, the first sub-encoder, and the switch. The interleaver interleaves the input signal into an interleaved data sequence. The first sub-encoder encodes the input sequence into a first coded sequence. The second sub-encoder encodes the input sequence into a second coded sequence. The switch is settable to provide the second coded sequence as a switch output sequence when the system is in turbo coding/decoding mode, and to provide the interleaved data sequence as a switch output sequence when the system is in degenerated turbo coding/decoding mode. And the multiplexer multiplexes the data sequence, the first coded sequence, and the switch output sequence into an output sequence

In a further preferred embodiment, the decoder comprises: a separator, a first sub-decoder connected to the separator, a second sub-decoder connected to the separator, a first switch connected to the sub-decoders, and a second switch connected between the separator and the sub-decoders. The separator separates the received data sequence into a first, a second, and a third data sub-sequence. The first sub-decoder decodes the sub-sequences when the encoder-decoder system is in relatively complex mode. The second sub-decoder decodes the sub-sequences when the encoder-decoder system is in relatively simple mode. The first switch connects the decoder output to the first sub-decoder output when the decoder is in relatively complex decoding mode, and connects the decoder output to the second sub-decoder output when the decoder is in relatively simple decoding mode. And the second switch routes the sub-sequences to either of the first and second sub-decoders in accordance with a current mode of operation.

In a further preferred embodiment, the encoder-decoder system further comprises an automatic controller, connected to the encoder switch and to the decoder first switch, the automatic controller being operable to monitor predetermined communication parameters in order to determine a required one of the encoder-decoder system modes, and to control switch operation accordingly.

In a further preferred embodiment, the first sub-decoder comprises a turbo code decoder.

In another preferred embodiment, the second sub-decoder comprises: a de-interleaver, connected to the separator, for de-interleaving the third sub-sequence to form a de-interleaved sub-sequence, and a convolutional code decoder, connected to the separator and to the de-interleaver, for decoding the first sub-sequence, the second sub-sequence, and the de-interleaved sub-sequence into the estimate of an input sequence.

In a further preferred embodiment, the encoder-decoder system further comprises an automatic controller, connected to the second switch, the automatic controller being operable to monitor predetermined communication parameters in order to determine a required one of the decoder modes, and to control switch operation accordingly.

According to a fourth aspect of the present invention there is thus provided a method for encoding an input data sequence into an error protection encoded output sequence, comprising: receiving an input data sequence, interleaving the input sequence to form an interleaved data sequence, encoding the input sequence to form a first encoded sequence according to a first coding rule, encoding the interleaved sequence to form a second encoded sequence according to a second coding rule, selecting either one of the interleaved and the second encoded sequence, and multiplexing the input sequence, the first encoded sequence, and the selected sequence to form the error protection encoded output sequence.

In a preferred embodiment, the selection is made based on current values of predetermined communication parameters.

In a further preferred embodiment, the first encoding rule comprises convolutional coding.

In a further preferred embodiment, the second encoding rule comprises convolutional coding.

According to a fifth aspect of the present invention there is thus provided a method for decoding a received sequence comprising error-protection encoded data received from a noisy channel into an estimate of an input sequence, comprising: receiving the sequence from the noisy channel, separating the received sequence into a first, a second, and a third data sub-sequence, selecting either one of a first sub-decoder and a second sub-decoder, and decoding the sub-sequences into the estimate of an input sequence using the selected sub-decoder.

In a preferred embodiment, selection is made based on current values of predetermined communication parameters.

In a further preferred embodiment, the first sub-decoder comprises a turbo code decoder.

In a further preferred embodiment, the method by which the second sub-decoder decodes the first, second, and third data sub-sequences comprises: de-interleaving the third sub-sequence into a deinterleaved sub-sequence, and decoding the first, the second, and the de-interleaved sub-sequences into the estimate of an input sequence using a convolutional code decoder.

In a further preferred embodiment, the convolutional code decoder comprises a hard-decision trellis decoder.

In another preferred embodiment, the convolutional code decoder comprises a soft-decision trellis decoder.

### BRIEF DESCRIPTION OF THE DRAWINGS

For a better understanding of the invention and to show how the same may be carried into effect, reference will now be made, purely by way of example, to the accompanying drawings, in which:

FIG. 1 shows a simplified block diagram of a conventional turbo code encoder.

FIG. 2 shows a simplified block diagram of a switchable output encoder according to a preferred embodiment of the present invention.

FIG. 3 shows a simplified block diagram of a switchable output encoder according to a preferred embodiment of the present invention.

FIG. 4 shows a simplified block diagram of a switchable decoder according to a preferred embodiment of the present invention.

FIG. 5 shows a simplified block diagram of a simple sub-decoder according to a preferred embodiment of the present invention.

FIG. 6 is a simplified flow chart of a method for encoding an input sequence according to a preferred embodiment of the present invention.

FIG. 7 is a simplified flow chart of a method for decoding a received sequence containing error-protection encoded data according to a preferred embodiment of the present invention.

FIG. 8 is a simplified flow chart of a method for use by a sub-decoder for decoding received sub-sequences according to a preferred embodiment of the present invention.

### DETAILED DESCRIPTION OF THE EMBODIMENTS

Currently known iterative decoding algorithms are significantly less complex than optimal decoding, yet remain computationally complex due to the use of costly component decoders. While the number of system users and the channel characteristics vary over the lifetime of a system, existing systems provide only a single coding solution, which may be sub-optimal for the existing conditions. There is a need for a more flexible data coding system. The dual-mode coding system embodiments described below provide a solution that enables trading data rate with signal to interference noise ratio (SINR) when conditions allow.

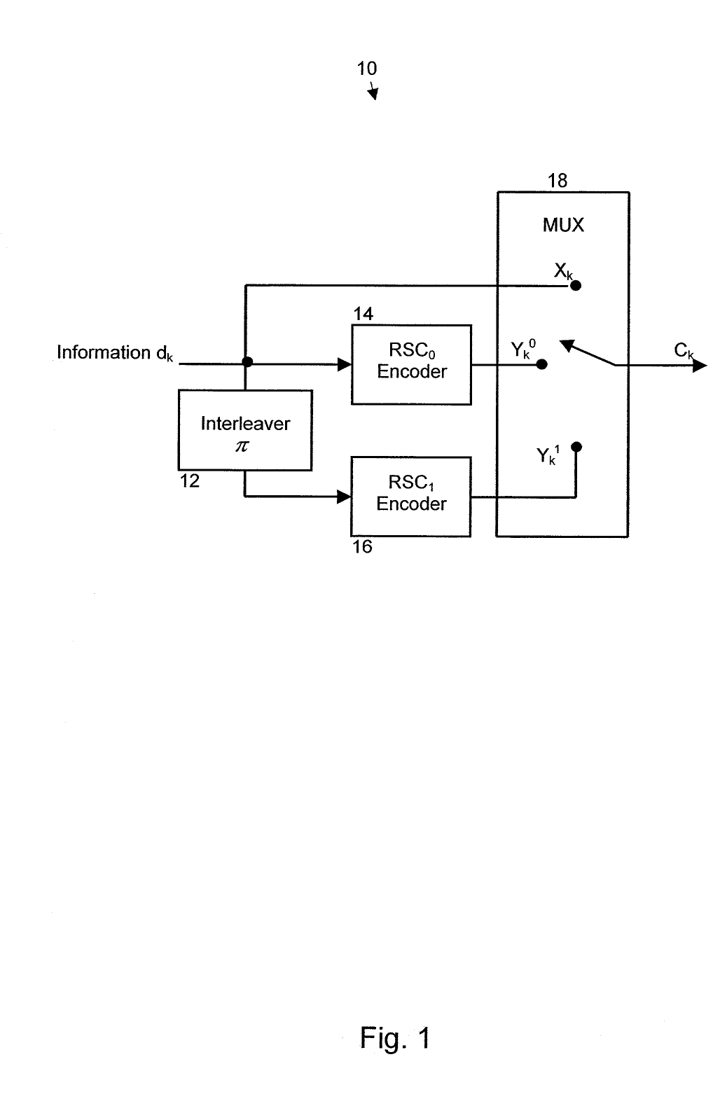

Reference is now made to FIG. 1, which is a simplified block diagram of a conventional turbo code encoder 10. The encoder 10 comprises an interleaver 12, two recursive systematic convolutional (RSC) encoders 14 and 16, and a multiplexer 18. The input to the turbo code encoder 10 is an input data sequence d. The first encoder RSC₀ 14 encodes the input data sequence d directly, forming data sequence Y⁰. Interleaver 12 interleaves the input data sequence d. The interleaved sequence is the input to the second encoder RSC₁ 16. RSC₁ encoder 16 encodes the interleaved version of data sequence d, forming data sequence Y¹. The multiplexer 18 combines the three data sequences into output sequence C. The coded sequence is given by {Cₖ}, with Cₖ=(Xₖ, Yₖ⁰, Yₖ¹), where Xₖ=dₖ is the information bit at time k, Yₖ⁰ is the parity output bit from the encoder RSC₀ 14, and Yₖ¹ is the parity output bit from the encoder RSC₁ 16. This output sequence is then transmitted over a noisy channel. For notational simplicity, when reference is made to an entire sequence, the k subscript, used to indicate a specific bit in the sequence, will be omitted.

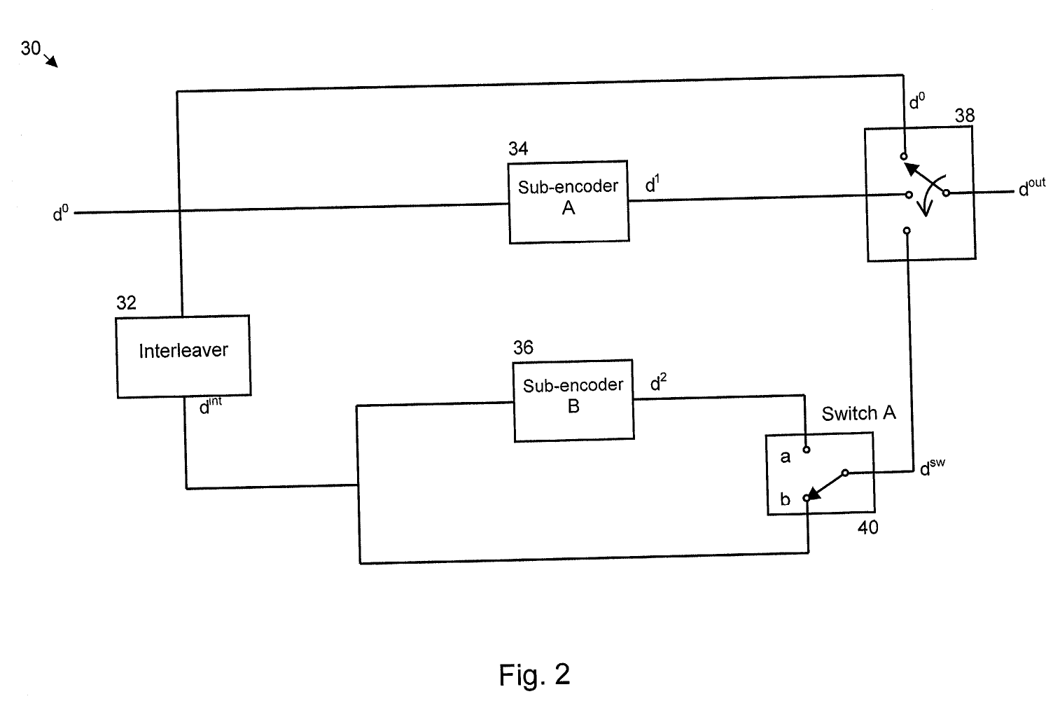

Reference is now made to FIG. 2, which is a simplified block diagram of a switchable output encoder 30 according to a first embodiment of the present invention. The encoder 30 encodes an input data sequence to form an error-protection encoded output sequence, for transmission over a noisy channel. Encoder 30 operates in two encoding modes: a relatively complex mode, suitable for a relatively high noise level channel, and a relatively simple mode, suitable for a relatively low noise level channel. The relatively complex mode comprises a turbo coding mode. In a preferred embodiment, the relatively simple mode is a degenerated form of the relatively complex mode. The encoder 30 comprises interleaver 32, sub-encoder A 34, sub-encoder B 36, and multiplexer 38, all of which operate in a manner similar to those of the encoder of FIG. 1. The encoder 30 additionally comprises switch A 40, which determines the composition of the encoder output according to a selected encoding mode.

The input to the switchable-output encoder 30 is an input data sequence d⁰. Sub-encoder A 34 encodes the input data sequence d⁰ directly, forming data sequence d¹. Interleaver 12 interleaves the input data sequence d⁰, to form d^{int}. This interleaved sequence d^{int} is the input to sub-encoder B 36. Sub-encoder B 36 encodes d^{int}, forming data sequence d². Unlike the turbo encoder described above, data sequence d² is not input directly to one of the multiplexer inputs. Sequence d² serves as one of the inputs to switch A 40. The second input to switch A 40 is the interleaved sequence d^{int}. The switch output sequence d^{SW} is selected according to the current encoding mode. When the encoder 30 is in relatively complex mode, switch A 40 is set to position a, and the switch output sequence d^{SW} is sequence d². When the encoder 30 is in relatively simple mode, sub-encoder 36 B is bypassed. In this mode, switch A 40 is set to position b, and the switch output sequence d^{SW} is sequence d^{int}. The multiplexer 38 combines the three data sequences, d⁰, d¹, and d^{SW}, into output sequence d^{OUT}. The coded sequence is given by {dₖ^{OUT}}, with dₖ^{OUT}=(dₖ⁰, dₖ¹, dₖ^{SW}), where dₖ⁰ is the information bit at time k, dₖ¹ is the parity output bit from sub-encoder A 34, and dₖ^{SW} is the parity output bit from switch A 40.

In the preferred embodiment of the encoder, sub-encoder A 34 and sub-encoder B 36 are recursive systematic convolutional (RSC) encoders. The relatively complex encoder mode is equivalent to conventional turbo encoding, and the relatively simple mode is a degenerated turbo coding mode.

In an alternate preferred embodiment, the relatively simple mode comprises a convolutional coding mode.

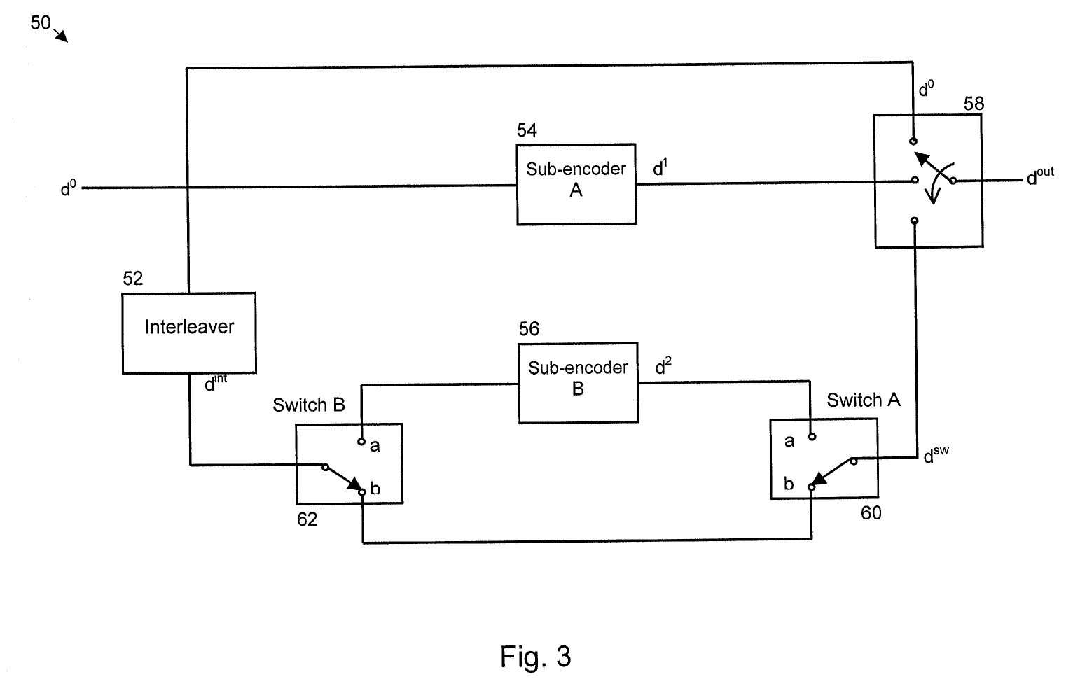

Reference is now made to FIG. 3, which is a simplified block diagram of a further preferred embodiment of a switchable output encoder 50. This embodiment is similar to the embodiment of FIG. 2, with the addition of switch B 62 introduced after interleaver 52. Switch B 62 is synchronized with switch A 60, so that the interleaver output sequence d^{int} is connected to encoder B 56 only when the encoder 50 is in relatively complex mode. When the encoder 50 is in relatively simple mode, d^{int} is connected to switch A 60, thereby eliminating an unnecessary encoding of the interleaved sequence.

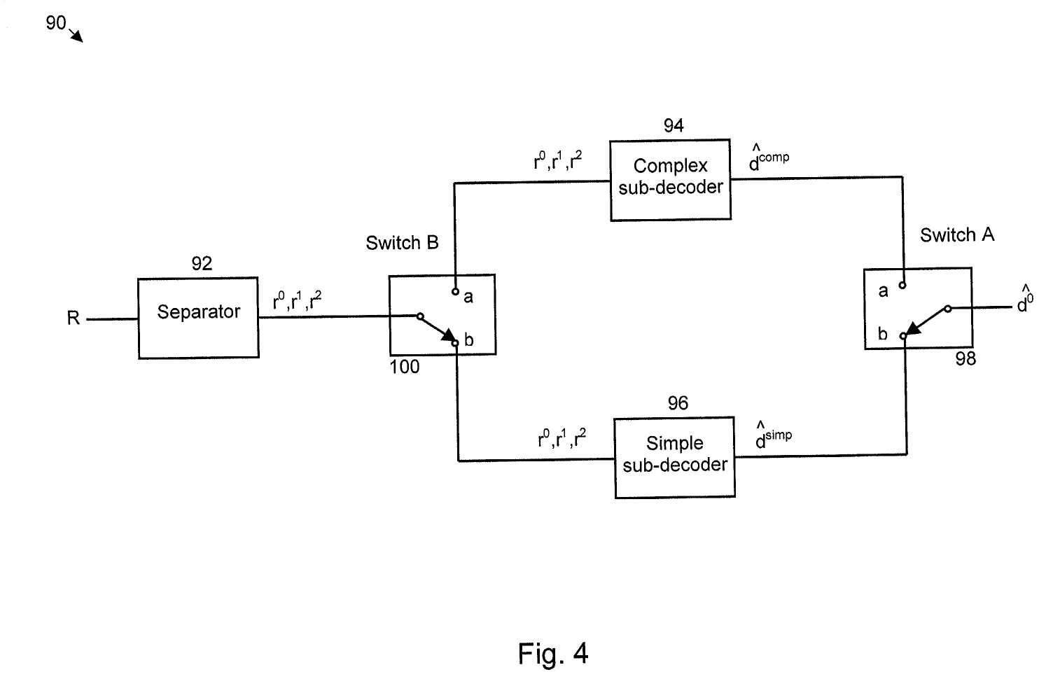

Reference is now made to FIG. 4, which is a simplified block diagram of a preferred embodiment of a switchable decoder 90. Switchable decoder 90 decodes a received sequence R containing error-protection encoded data received from a noisy channel, into an estimate of an input sequence. The decoder operates in two decoding modes corresponding to the two aforementioned encoding modes: a relatively complex mode suitable for a relatively high noise level channel and a relatively simple mode suitable for a relatively low noise level channel. In a preferred embodiment, the relatively simple mode is a degenerated version of the relatively complex mode.

Switchable decoder 90 comprises separator 92, complex sub-decoder 94, simple sub-decoder 96, a switch A 98, and a switch B 100. Switch B 100 is synchronized with switch A 98, so that the separator output sub-sequences are connected to complex sub-decoder 94 only when the decoder 90 is in relatively complex mode. When the decoder 90 is in relatively simple mode, the separator output sub-sequences are connected to simple sub-decoder 96. Separator 92 processes a multiplexed received data sequence, to separate the multiplexed sequence into its component sub-sequences, r⁰, r¹, and r². The component sub-sequences are then decoded by complex sub-decoder 94, to form decoded sequence \hat{d}^{comp}, or by simple sub-decoder 96, to form decoded sequence \hat{d}^{simp}. The decoded sequence is the input to switch A 98, which selects an output sequence \hat{d}⁰ according to the current decoding mode. When the decoder 90 is in relatively complex mode, switches A 98 and B 100 are set to position a, and the switch output sequence \hat{d}⁰ is thus formed by sequence \hat{d}^{comp}. When the decoder 90 is in relatively simple mode, switches A 98 and B 100 are set to position b, and the switch output sequence \hat{d}⁰ is formed by sequence \hat{d}^{simp}.

Specific embodiments of the sub-decoders are determined by the coding method used prior to transmission. In a preferred embodiment of a complex sub-decoder, the received data sequence input to the decoder is turbo code encoded, and the complex sub-decoder is a turbo code decoder known in the art.

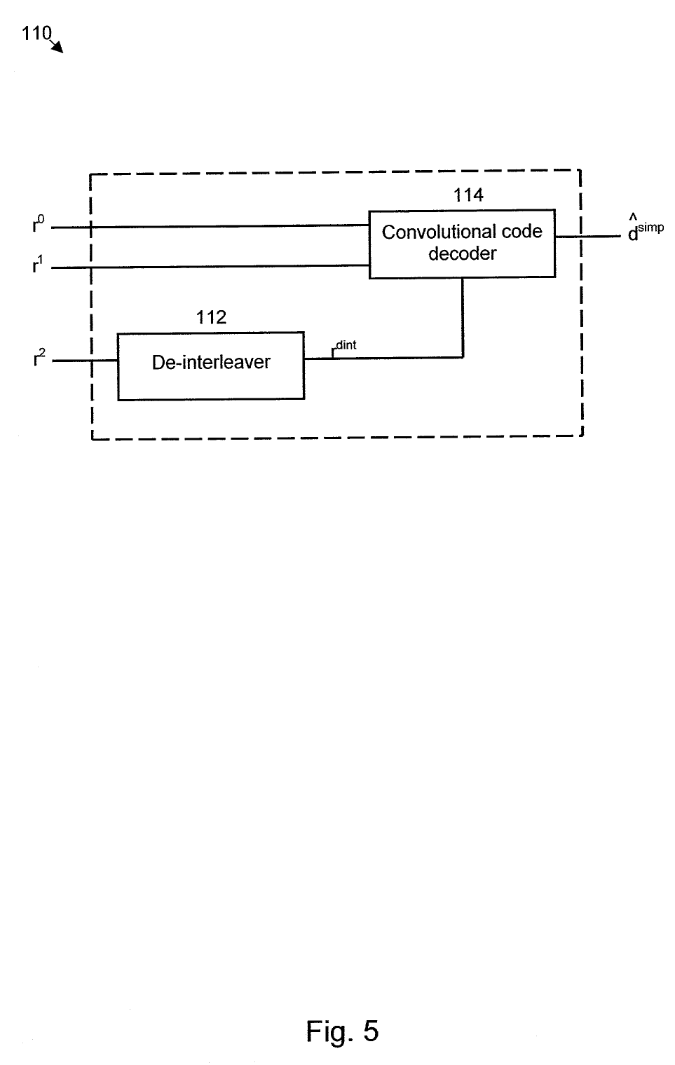

Reference is now made to FIG. 5, which is a simplified block diagram of a preferred embodiment of a simple sub-decoder 110. The inputs to the sub-decoder 110 are the sub-sequences r⁰, r¹, and r². In the preferred embodiment, sub-decoder 110 is a component of the switchable decoder described above for FIG. 4, and the sub-sequences are provided by a separator, as previously described. In the preferred embodiment, sub-sequence r⁰ is a noisy version of the input signal. Sub-sequence r¹ is a noisy version of a sub-sequence formed by encoding the input signal. In a preferred embodiment the encoding method used to form sub-sequence r¹ is convolutional coding. Sub-sequence r² is a noisy version of a sub-sequence formed by interleaving the input signal. First, sub-sequence r² is de-interleaved by de-interleaver 112, to form r^{dint}. Like sequence r⁰, sequence r^{dint} is a noisy version of the input signal. After de-interleaving, the values (rₖ⁰, rₖ¹, rₖ^{dint}) are all associated with the k-th bit of the input sequence. Since rₖ⁰ and rₖ^{dint} were received at different times, their noise content is statistically independent. The de-interleaved sequence r^{dint} thereby introduces new information about the input sequence, which can be used by sub-decoder 110 during the decoding process. The sequences r⁰, r¹, and r^{dint} are input into a convolutional code decoder 114, which decodes them into an estimate of the input sequence \hat{d}^{simp}. In one preferred embodiment, convolutional code decoder 114 is a non-iterative soft-decision trellis decoder known in the art. In another preferred embodiment, convolutional code decoder 114 is a non-iterative hard-decision trellis decoder known in the art. Sub-sequences r⁰, r¹, and r^{dint} are used to calculate the convolutional code decoder metrics.

In a preferred embodiment, the simple sub-decoder is a component of the complex sub-decoder.

Preferably, the switchable-output encoder and the switchable decoder operate as a system. In such a system, the switches in the encoder and decoder are synchronized, so that both the encoder and the decoder operate in the same mode. The complex sub-decoder decodes output sequences produced by the encoder during complex mode operation, and the simple sub-decoder decodes output sequences produced by the encoder during simple mode operation.

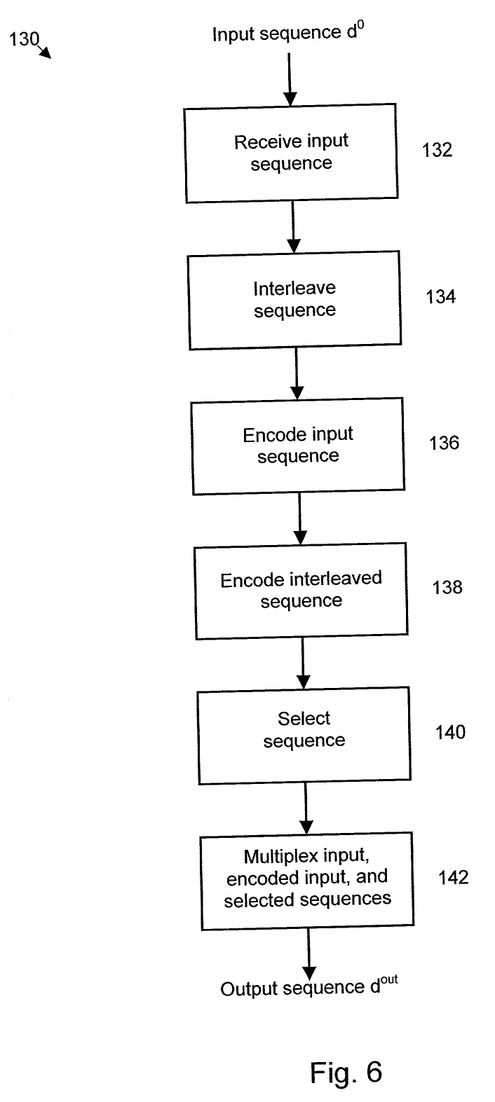

Reference is now made to FIG. 6, which is a simplified flow chart of a method for encoding an input sequence according to a preferred embodiment of the present invention. The input data sequence d⁰ is received in step 132. An interleaved sequence, d^{int}, is formed in step 134 by interleaving d⁰. In step 136, sequence d⁰ is encoded to form sequence d¹. In step 138, the interleaved sequence d^{int} is encoded to form an additional sequence d². The encoding rule used to form sequence d² may differ from the encoding rule used to form sequence d¹. One of the sequences d^{int} or d² is selected in step 140. Finally, in step 142, an output sequence d^{OUT} is formed by multiplexing d⁰, d¹, and the selected sequence into a single error-protection encoded sequence.

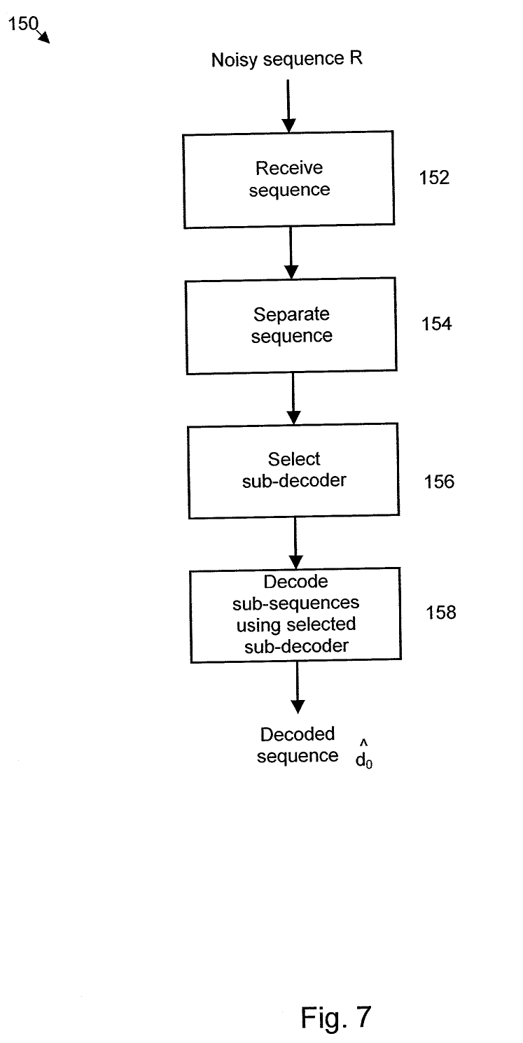

Reference is now made to FIG. 7, which is a simplified flow chart of a method for decoding a received sequence containing error-protection encoded data according to a preferred embodiment of the present invention. Received signal R is input to the system in step 152. In step 154, R is separated into component sub-sequences r⁰, r¹, and r². A sub-decoder is selected in step 156. The selected decoder decodes the sub-sequences to form an estimate of an input sequence, \hat{d}⁰, in step 158. This estimated sequence serves as the decoder output.

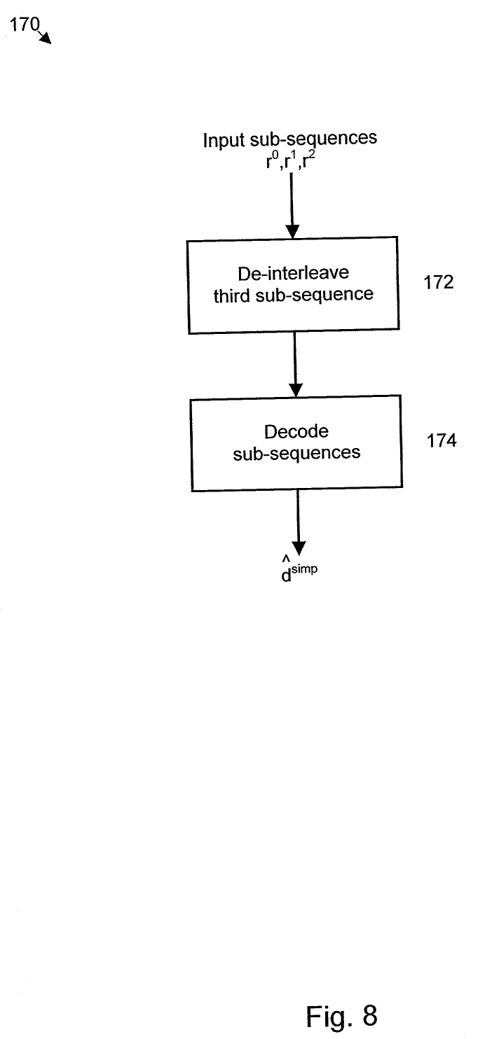

Reference is now made to FIG. 8, which is a simplified flow chart of an embodiment of a method suitable for use by a sub-decoder for decoding received sub-sequences. First, sub-sequences r⁰, r¹, and r² are received in step 172. In a preferred embodiment, these sequences correspond to those of the method of FIG. 7 described above. These sub-sequences are decoded in step 174 by a convolutional code decoder into an estimate of an original data sequence \hat{d}^{simp}.

When deploying cellular wireless networks, systems are often designed to meet certain quality of service (QoS) requirements by employing sophisticated and computationally demanding error correction schemes. During the early stages of deployment there may be only a small number of users, and consequently lower levels of interference. Nevertheless, even with only a few customers in a system (i.e., lower interference levels), complex error correction is still provided at the handsets. Alternatively, standard DSPs may be used, resulting in lower peak data rates. The present embodiments can be employed to ease this problem, typically encountered in the early stages of network deployment, by allowing an increase in the data rate without sacrificing the QoS.

In later stages of network deployment, the present embodiments may be used for trading data rate with SINR when the conditions allow an increase in the SINR. For example, when the user is near the base station the power transmitted by the base station to that particular user is relatively low, and can be increased without significantly affecting other users in the cell or neighboring cells.

The present embodiments provide a switchable coding system which can operate over a variety of conditions. The relatively complex mode provides a robust solution for networks operating with a high number of users, or under poor SINR conditions. The relatively simple mode is suitable for systems operating with low numbers of users, or with high SINR. The relatively simple coding mode provides a simpler coding and decoding technique, requiring less processing and enabling a higher data rate. The current system mode of operation is preferably selected automatically, according to detected network and channel conditions.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable subcombination.

It will be appreciated by persons skilled in the art that the present invention is not limited to what has been particularly shown and described hereinabove. Rather the scope of the present invention is defined by the appended claims and includes both combinations and subcombinations of the various features described hereinabove as well as variations and modifications thereof which would occur to persons skilled in the art upon reading the foregoing description.

We claim:

1. A switchable-output encoder for encoding an input data sequence to form an error protection encoded output sequence, wherein said encoder is switchable between two encoding modes, said modes comprising a relatively complex mode suitable for a relatively high noise level channel and a relatively simple mode suitable for a relatively low noise level channel, wherein said relatively complex mode comprises a turbo coding mode.

2. A switchable-output encoder according to claim 1, wherein said relatively simple mode comprises a degenerated version of said relatively complex mode.

3. A switchable-output encoder according to claim 1, wherein said relatively simple mode comprises a degenerated turbo coding mode.

4. A switchable-output encoder according to claim 1, wherein said relatively simple mode comprises a convolutional coding mode.

5. A switchable-output encoder according to claim 1, wherein, in said turbo coding mode, said output sequence comprises a multiplexed sequence containing at least three sub-sequences, said sub-sequences including a data sequence, a first coded sequence formable by encoding said data sequence, and a second coded sequence formable by interleaving said data sequence into an interleaved sequence and encoding said interleaved sequence.

6. A switchable-output encoder according to claim 3, wherein, in said degenerated turbo coding mode, said output sequence comprises a multiplexed sequence containing at least three sub-sequences, said sub-sequences including a data sequence, a first coded sequence formable by encoding said data sequence, and an interleaved sequence formable by interleaving said data sequence.

7. A switchable-output encoder according to claim 3, comprising a first sub-encoder, to encode said input data sequence into a first coded sequence.

8. A switchable-output encoder according to claim 7, wherein said encoder comprises an interleaver, to interleave said input data sequence into an interleaved sequence.

9. A switchable-output encoder according to claim 8, further comprising a second sub-encoder, connected to said interleaver, to encode said interleaved data sequence into a second coded sequence.

10. A switchable-output encoder according to claim 9, further comprising a switch connected to said interleaver and to said second sub-encoder, wherein said switch is operable to provide one of said interleaved sequence and said second coded sequence as a switch output sequence, thereby affecting the composition of said encoder output sequence.

11. A switchable-output encoder according to claim 10, further comprising an automatic controller, connected to said switch, said automatic controller being operable to monitor predetermined communication parameters in order to determine a required one of said encoder modes, and to control switch operation accordingly.

12. A switchable-output encoder according to claim 10, wherein in order to provide said turbo coding mode, said switch is settable to send said second coded sequence for output, and in order to provide said degenerated turbo coding mode, said switch is settable to send said interleaved sequence for output.

13. A switchable-output encoder according to claim 10, further comprising a multiplexer, connected to said encoder input, to said first sub-encoder, and to said switch, to multiplex said input data sequence, said first encoded sequence, and said switch output sequence into a single multiplexed sequence.

14. A switchable-output encoder according to claim 13, wherein said multiplexed sequence serves as said error-protection encoded output sequence.

15. A switchable-output encoder according to claim 7, wherein said first sub-encoder comprises a convolutional coder.

16. A switchable-output encoder according to claim 9, wherein said second sub-encoder comprises a convolutional coder.

17. A switchable-output encoder according to claim 9, wherein said first sub-encoder and said second sub-encoder are recursive systematic convolutional encoders.

18. A switchable decoder for decoding a received sequence comprising error-protection encoded data, received from a noisy channel into an estimate of an input sequence, wherein said decoder is switchable between two modes, said modes comprising a relatively complex decoding mode suitable for a relatively high noise level channel and a relatively simple decoding mode suitable for a relatively low noise level channel, and wherein said relatively complex mode comprises a turbo decoding mode.

19. A switchable decoder according to claim 18, wherein said relatively simple decoding mode comprises a degenerated version of said relatively complex decoding mode.

20. A switchable decoder according to claim 18, wherein said relatively simple decoding mode comprises a degenerated turbo decoding mode.

21. A switchable decoder according to claim 18, wherein said relatively simple decoding mode comprises a convolutional decoding mode.

22. A switchable decoder according to claim 20, operable to process said received sequence as a multiplexed sequence comprising at least three component sub-sequences.

23. A switchable decoder according to claim 22, wherein, when said decoder is in degenerated turbo decoding mode, said decoder is operable to process said first sub-sequence as a data sequence, said second sub-sequence as a directly encoded sub-sequence, and said third sub-sequence as an interleaved data sub-sequence.

24. A switchable decoder according to claim 18, comprising a separator, operable to separate the received data sequence into a first, a second, and a third data sub-sequence.

25. A switchable decoder according to claim 24, further comprising a first switch, connected to said sub-decoders, wherein said first switch is operable to connect the decoder output to the first sub-decoder output when said decoder is in relatively complex decoding mode, and to connect the decoder output to the second sub-decoder output when said decoder is in relatively simple decoding mode.

26. A switchable decoder according to claim 25, wherein said first sub-decoder is operable as a turbo decoder, and said second sub-decoder is operable as a degenerated turbo decoder.

27. A switchable decoder according to claim 26, wherein said degenerated turbo decoder comprises a de-interleaver for de-interleaving said third sub-sequence to form a de-interleaved sub-sequence.

28. A switchable decoder according to claim 27, wherein said degenerated turbo decoder further comprises a convolutional code decoder for decoding said first sub-sequence, said second sub-sequence, and said de-interleaved sub-sequence into said estimate of an input sequence.

29. A switchable decoder according to claim 28, wherein said convolutional code decoder comprises a hard-decision trellis decoder.

30. A switchable decoder according to claim 28, wherein said convolutional code decoder comprises a soft-decision trellis decoder.

31. A switchable decoder according to claim 25, further comprising a second switch, connected to said separator, wherein when said decoder is in relatively complex decoding mode said second switch is settable to connect said separator output sub-sequences to inputs of said first sub-decoder, and when said decoder is in relatively simple decoding mode said second switch is settable to connect said separator outputs to inputs of said second sub-decoder.

32. A switchable decoder according to claim 25, further comprising an automatic controller connected to said first switch, said automatic controller being operable to monitor predetermined communication parameters in order to determine a required one of said decoder modes, and to control switch operation accordingly.

33. A switchable decoder according to claim 31, further comprising an automatic controller, connected to said second switch, said automatic controller being operable to monitor predetermined communication parameters in order to determine a required one of said decoder modes, and to control switch operation accordingly.

34. A switchable data encoder-decoder system, comprising a switchable-output encoder for encoding an input sequence to form an error protection encoded output sequence and a switchable decoder, for decoding a received sequence into an estimate of said input sequence, wherein said encoder and said decoder are synchronously switchable between two modes of operation, said modes comprising a relatively complex mode suitable for a relatively high noise level channel and a relatively simple mode suitable for a relatively low noise level channel, and wherein said relatively complex mode comprises a turbo coding/decoding mode.

35. A switchable data encoder-decoder system according to claim 34, wherein said relatively simple mode comprises a degenerated version of said relatively complex mode.

36. A switchable data encoder-decoder system according to claim 34, wherein said relatively simple mode comprises a degenerated turbo coding/decoding mode.

37. A switchable data encoder-decoder system according to claim 34, wherein said relatively simple mode comprises a convolutional coding/decoding mode.

38. A switchable data encoder-decoder system according to claim 36, wherein when said encoder-decoder system is in turbo coding/decoding mode said encoder is operable to output a multiplexed signal comprising three sub-sequences, said sub-sequences comprising said input data sequence, a first coded sequence, and an interleaved and encoded data sequence.

39. A switchable data encoder-decoder system according to claim 38, wherein when said encoder-decoder system is in degenerated turbo coding/decoding mode said encoder is operable to output a multiplexed signal comprising three sub-sequences, said sub-sequences comprising said input data sequence, a first coded sequence, and an interleaved data sequence.

40. A switchable data encoder-decoder system according to claim 39, wherein when said encoder-decoder system is in degenerated turbo coding/decoding mode said decoder is operable to decode a received version of a multiplexed signal comprising said input data sequence, a first coded sequence, and an interleaved data sequence into an estimate of said input sequence.

41. A switchable data encoder-decoder system according to claim 34, wherein said encoder comprises:
an interleaver to interleave said input signal into an interleaved data sequence;
a first sub-encoder, to encode said input sequence into a first coded sequence;
a second sub-encoder, connected to said interleaver, to encode said input sequence into a second coded sequence;
a switch, connected to said interleaver and to said second sub-encoder, settable to provide said second coded sequence as a switch output sequence when said system is in turbo coding/decoding mode, and to provide said interleaved data sequence as a switch output sequence when said system is in degenerated turbo coding/decoding mode; and,
a multiplexer, connected to said encoder input, said first sub-encoder, and said switch, to multiplex said data sequence, said first coded sequence, and said switch output sequence into an output sequence.

42. A switchable data encoder-decoder system according to claim 41, wherein said decoder comprises:
a separator, operable to separate the received data sequence into a first, a second, and a third data sub-sequence;
a first sub-decoder, connected to said separator, operable to decode said sub-sequences when said encoder-decoder system is in relatively complex mode;
a second sub-decoder, connected to said separator, operable to decode said sub-sequences when said encoder-decoder system is in relatively simple mode;
a first switch, connected to said sub-decoders, to connect the decoder output to the first sub-decoder output when said decoder is in relatively complex decoding mode, and to connect the decoder output to the second sub-decoder output when said decoder is in relatively simple decoding mode; and,
a second switch, connected between said separator and said sub-decoders, settable to route said sub-sequences to either of the first and second sub-decoders in accordance with a current mode of operation.

43. A switchable data encoder-decoder system according to claim 42, wherein said encoder-decoder system further comprises an automatic controller, connected to said encoder switch and to said decoder first switch, said automatic controller being operable to monitor predetermined communication parameters in order to determine a required one of said encoder-decoder system modes, and to control switch operation accordingly.

44. A switchable data encoder-decoder system according to claim 42, wherein said first sub-decoder comprises a turbo code decoder.

45. A switchable data encoder-decoder system according to claim 42, wherein said second sub-decoder comprises:
a de-interleaver, connected to said separator, for de-interleaving said third sub-sequence to form a de-interleaved sub-sequence; and,
a convolutional code decoder, connected to said separator and to said de-interleaver, for decoding said first sub-sequence, said second sub-sequence, and said de-interleaved sub-sequence into said estimate of an input sequence.

46. A switchable data encoder-decoder system according to claim 42, further comprising an automatic controller, connected to said second switch, said automatic controller being operable to monitor predetermined communication parameters in order to determine a required one of said decoder modes, and to control switch operation accordingly.

47. A method for encoding an input data sequence into an error protection encoded output sequence, comprising:
receiving an input data sequence;
interleaving said input sequence to form an interleaved data sequence;
encoding said input sequence to form a first encoded sequence according to a first coding rule;
encoding said interleaved sequence to form a second encoded sequence according to a second coding rule;
selecting either one of said interleaved and said second encoded sequence; and,
multiplexing said input sequence, said first encoded sequence, and said selected sequence to form said error protection encoded output sequence.

48. A method for encoding an input data sequence into an error protection encoded output sequence according to claim 47, wherein selection is made based on current values of predetermined communication parameters.

49. A method for encoding an input data sequence into an error protection encoded output sequence according to claim 47, wherein said first encoding rule comprises convolutional coding.

50. A method for encoding an input data sequence into an error protection encoded output sequence according to claim 47, wherein said second encoding rule comprises convolutional coding.

51. A method for decoding a received sequence comprising error-protection encoded data received from a noisy channel into an estimate of an input sequence, comprising:
receiving said sequence from said noisy channel;
separating said received sequence into a first, a second, and a third data sub-sequence;
selecting either one of a first sub-decoder and a second sub-decoder; and,
decoding said sub-sequences into said estimate of an input sequence using the selected sub-decoder.

52. A method for decoding a received sequence comprising error-protection encoded data received from a noisy channel into an estimate of an input sequence according to claim 51, wherein selection is made based on current values of predetermined communication parameters.

53. A method for decoding a received sequence comprising error-protection encoded data received from a noisy channel into an estimate of an input sequence according to claim 51, wherein said first sub-decoder comprises a turbo code decoder.

54. A method for decoding a received sequence comprising error-protection encoded data received from a noisy channel into an estimate of an input sequence according to claim 51, wherein the method by which said second sub-decoder decodes said first, second, and third data sub-sequences comprises:
de-interleaving said third sub-sequence into a deinterleaved sub-sequence; and,
decoding said first, said second, and said de-interleaved sub-sequences into said estimate of an input sequence using a convolutional code decoder.

55. A method for decoding a received sequence comprising error-protection encoded data received from a noisy channel into an estimate of an input sequence according to claim 54, wherein said convolutional code decoder comprises a hard-decision trellis decoder.

56. A method for decoding a received sequence comprising error-protection encoded data received from a noisy channel into an estimate of an input sequence according to claim 54, wherein said convolutional code decoder comprises a soft-decision trellis decoder.
